(19) United States
(12) Patent Application Publication
(10) Pub. No.: US 2014/0319495 A1
(43) Pub. Date: Oct. 30, 2014

(54) NOVEL ORGANIC COMPOUND, ORGANIC LIGHT-EMITTING DEVICE, AND IMAGE DISPLAY SYSTEM

(71) Applicant: CANON KABUSHIKI KAISHA, Tokyo (JP)

(72) Inventors: Masumi Itabashi, Kodaira-shi (JP); Hirokazu Miyashita, Tokyo (JP); Ryuji Ishii, Yokohama-shi (JP); Masanori Muratsubaki, Hachioji-shi (JP); Jun Kamatani, Tokyo (JP)

(73) Assignee: CANON KABUSHIKI KAISHA, Tokyo (JP)

(21) Appl. No.: 14/263,283

(22) Filed: Apr. 28, 2014

(30) Foreign Application Priority Data
Apr. 30, 2013 (JP) 2013-096001
Mar. 6, 2014 (JP) 2014-044266

(51) Int. Cl. H01L 29/08; C09B 5/00; C07F 7/02

(52) U.S. Cl. CPC H01L 51/0072; H01L 51/0052; H01L 51/0061; H01L 51/0094; H01L 51/52; G03G 15/04
USPC 257/40; 548/416; 548/406

(57) ABSTRACT

An organic compound has a dibenzo[8,9:10,11]tetrapheno[5,6-b]carbazole skeleton as a basic skeleton. An organic light-emitting device includes an anode, a cathode, and an organic compound layer including the organic compound. A display apparatus includes a plurality of pixels, and each of the pixels includes the organic light-emitting device and a transistor. An image display system includes an input section and a display section including the display apparatus. A lighting apparatus includes the organic light-emitting device and an inverter circuit. An electrophotographic image-forming apparatus includes a light source including a plurality of the organic light-emitting devices and a photosensitive member.

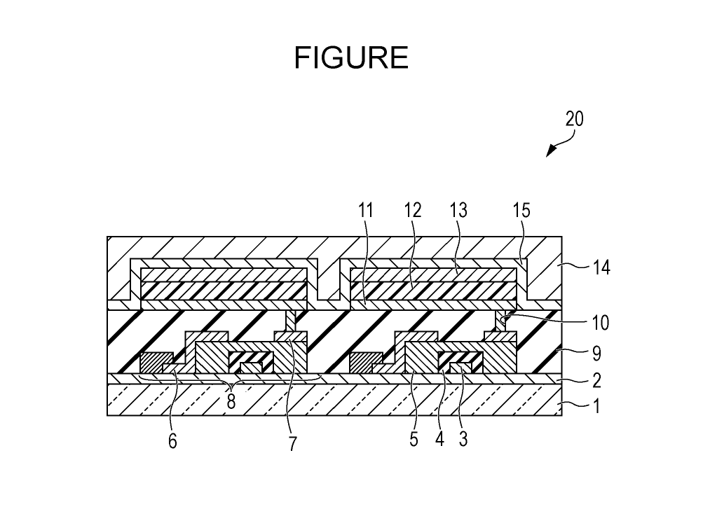

### BACKGROUND OF THE INVENTION

1. Field of the Invention

The present invention relates to a novel organic compound and to an organic light-emitting device and an image display system that are produced using the novel organic compound.

2. Description of the Related Art

An organic light-emitting device (also referred to as “organic electroluminescence device” or “organic EL device”) is an electronic device including a pair of electrodes and an organic compound layer interposed between the electrodes. Upon injection of electrons and holes from the pair of electrodes, a luminescent organic compound contained in the organic compound layer generates excitons. An organic light-emitting device emits light when the excitons return to the ground state.

Recently, there have been significant studies on organic light-emitting devices, in which efforts have been directed toward attaining low driving voltage, various light emission wavelengths, high-speed response, and reductions in the thickness and weight of a light-emitting device.

Organic compounds having a charge transportation capability have been created in order to reduce the driving voltage of a light-emitting device and to thereby reduce the power consumption of the light-emitting device.

Examples of such organic compounds include the following compound I-A described in International Publication No. WO2013/009095 and the following compound 1-B described in U.S. Patent Application Publication No. 2013/0043460.

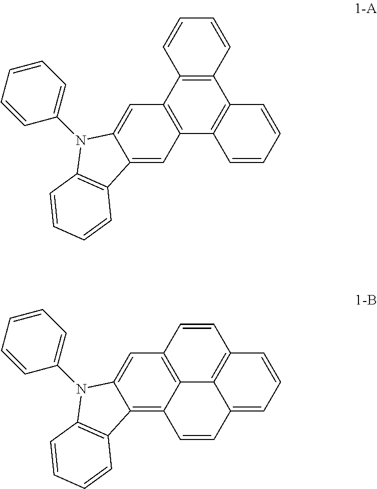 [SMILES: c1ccc(-n2c3ccccc3c3cc4c5ccccc5c5ccccc5c4cc32)cc1 ; c1ccc(-n2c3ccccc3c3c4ccc5cccc6ccc(cc32)c4c65)cc1]

However, the basic skeletons of the compounds described in International Publication No. WO2013/009095 and U.S. Patent Application Publication No. 2013/0043460 are not capable of realizing a good hole transportation capability, and there is still room for improvements.

### SUMMARY OF THE INVENTION

Accordingly, the present invention provides an organic compound represented by Structural Formula (1).

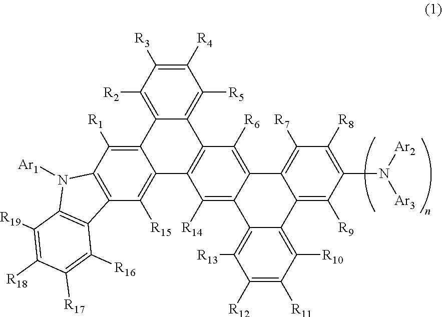

R₁ to R₁₉ are each independently selected from a hydrogen atom, a halogen atom, an alkyl group, an alkoxy group, and an aryl group. Ar₁ to Ar₃ each represent an aryl group, and n is 0 or 1.

The alkyl group, the alkoxy group, and the aryl group may have a substituent.

The substituent is selected from an alkyl group, an aralkyl group, an aryl group, an alkoxy group, a cyano group, and a halogen atom.

When n is 0, the 11H-dibenzo[8,9:10,11]tetrapheno[5,6-b]carbazole skeleton shown in Structural Formula (1) has a hydrogen atom.

The present invention also provides an organic compound represented by any one of Structural Formulae (A), (B), and (C).

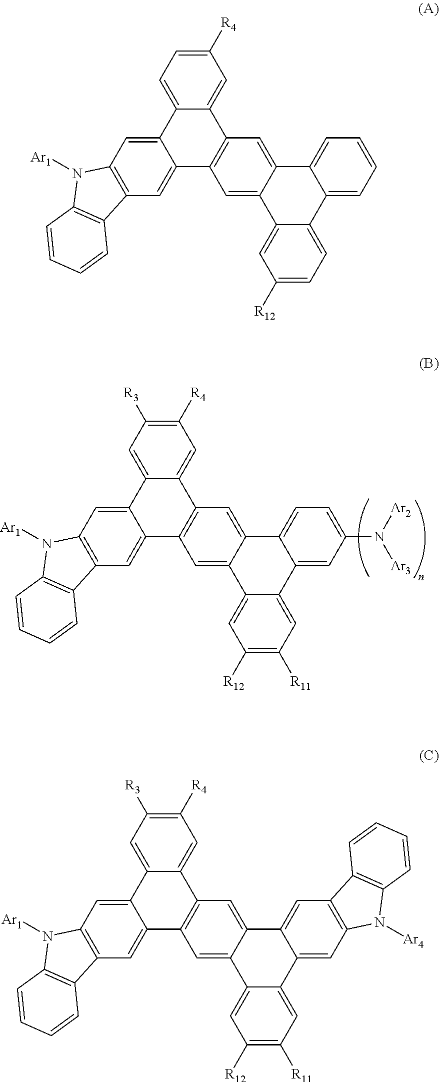

R₃, R₄, R₁₁, and R₁₂ are each independently selected from a hydrogen atom, a halogen atom, an alkyl group, an alkoxy group, and an aryl group. Ar₁ to Ar₄ each represent an aryl group, and n is 1.

The alkyl group, the alkoxy group, and the aryl group may have a substituent.

The substituent is selected from an alkyl group, an aralkyl group, an aryl group, an alkoxy group, a cyano group, and a halogen atom.

Further features of the present invention will become apparent from the following description of exemplary embodiments with reference to the attached drawing.

### BRIEF DESCRIPTION OF THE DRAWING

FIGURE is a schematic cross-sectional view of an example of a display apparatus including an organic light-emitting device according to an embodiment of the present invention and a transistor electrically connected to the organic light-emitting device.

### DESCRIPTION OF THE EMBODIMENTS

An organic compound according to an embodiment of the present invention is described below.

### Organic Compound

An example of the organic compound according to the embodiment is represented by Structural Formula (1) below.

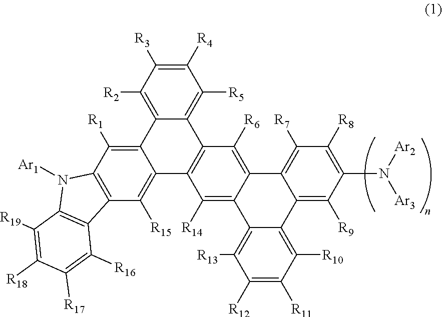

R₁ to R₁₉ are each independently selected from a hydrogen atom, a halogen atom, an alkyl group, an alkoxy group, and an aryl group. Ar₁ to Arₐ each represent an aryl group, and n is 0 or 1. When n is 0, the 11H-dibenzo[8,9:10,11]tetrapheno[5,6-b]carbazole skeleton shown in Structural Formula (1) has a hydrogen atom.

Specific examples of the alkyl group include a methyl group, an ethyl group, an n-propyl group, an n-butyl group, an n-pentyl group, an n-hexyl group, an n-heptyl group, an n-octyl group, an n-decyl group, an iso-propyl group, an iso-butyl group, a sec-butyl group, a tert-butyl group, an iso-pentyl group, a neopentyl group, a tert-octyl group, a fluoromethyl group, a difluoromethyl group, a trifluoromethyl group, a 2-fluoroethyl group, a 2,2,2-trifluoroethyl group, a perfluoroethyl group, a 3-fluoropropyl group, a perfluoropropyl group, a 4-fluorobutyl group, a perfluorobutyl group, a 5-fluoropentyl group, a 6-fluorohexyl group, a cyclopropyl group, a cyclobutyl group, a cyclopentyl group, a cyclohexyl group, a cyclopentylmethyl group, a cyclohexylmethyl group, a cyclohexylethyl group, and a 4-fluorocyclohexyl group. A methyl group, an ethyl group, an iso-propyl group, a tert-butyl group, and a trifluoromethyl group are preferable.

Specific examples of the alkoxy group include a methoxy group, an ethoxy group, an n-propoxy group, an iso-propoxy group, an n-butoxy group, an iso-butoxy group, a sec-butoxy group, a tert-butoxy group, an n-pentyloxy group, an n-hexyloxy group, and a phenoxy group. A methoxy group, an ethoxy group, and a phenoxy group are preferable.

Specific examples of the aryl group include a phenyl group, a naphthyl group, an indenyl group, a biphenyl group, a terphenyl group, a fluorenyl group, an anthryl group, a phenanthryl group, a pyrenyl group, a tetracenyl group, a pentacenyl group, a triphenyl group, and a perylenyl group. A phenyl group, a biphenyl group, a naphthyl group, and a fluorenyl group are preferable.

The alkyl group, the alkoxy group, the aryl group may have a substituent.

The substituent is selected from alkyl groups such as a methyl group, an ethyl group, a propyl group, and a butyl group; aralkyl groups such as a benzyl group; aryl groups such as a phenyl group and a biphenyl group; alkoxy groups such as a methoxy group, an ethoxy group, a propoxy group, and a phenoxy group; a cyano group; and halogen atoms such as fluorine, chlorine, bromine, and iodine.

It is preferable that Ar₁ is a phenyl group and R₁ to R₁₉ are all a hydrogen atom.

It is preferable that Arₑ and Arₐ are any one of a phenyl group and a fluorenyl group and n is 1.

The organic compound represented by Structural Formula (1) is a condensed polycyclic compound having an 1H-dibenzo[8,9:10,11]tetrapheno[5,6-b]carbazole skeleton as a basic skeleton. This organic compound has good linearity and thus realizes an enhanced degree of orientation. Therefore, this organic compound advantageously has a good hole transportation capability.

The organic compound represented by Structural Formula (1) has an order parameter S that satisfies −0.50≦S<−0.15. The order parameter S is represented by Expression (A) below.

S=(1/2)<3 cos² θ−1>=(Kₑ−Kₒ)/(Kₑ+2Kₒ) (A)

where θ represents the angle formed by the axis of molecules in a thin film formed by depositing an organic compound on a substrate and an axis normal to a substrate, and Kₒ and Kₑ represent substrate-horizontal-direction and substrate-vertical direction extinction coefficients, respectively, obtained by measuring the thin film by variable angle spectroscopic ellipsometry. In variable angle spectroscopic ellipsometry, optical constants such as an extinction coefficient are measured by changing the incidence angle and the wavelength of incident light. When all molecules are oriented in a direction parallel to the substrate, S is −0.50. In contrast, when all molecules are oriented in a direction perpendicular to the substrate, S is +1.00. When molecules are not oriented in a specific direction and are randomly arranged, S is 0.00.

Specific examples of the organic compound according to the embodiment include the following organic compounds. However, the present invention is not limited to the following organic compounds. Compounds of Groups A and B are exemplified compounds represented by Structural Formula (1) except that B5 and B9 are reference examples.

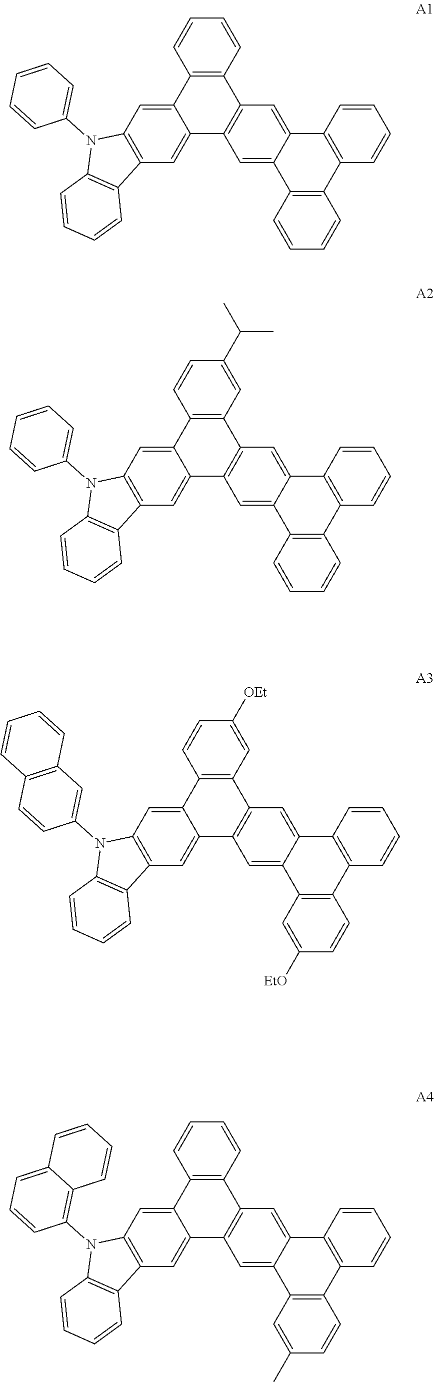 [SMILES: c1ccc(-n2c3ccccc3c3cc4c5cc6c7ccccc7c7ccccc7c6cc5c5ccccc5c4cc32)cc1 ; CC(C)c1ccc2c(c1)c1cc3c4ccccc4c4ccccc4c3cc1c1cc3c4ccccc4n(-c4ccccc4)c3cc21 ; CCOc1ccc2c3ccccc3c3cc4c5cc(OCC)ccc5c5cc6c(cc5c4cc3c2c1)c1ccccc1n6-c1ccc2ccccc2c1 ; Cc1ccc2c3ccccc3c3cc4c5ccccc5c5cc6c(cc5c4cc3c2c1)c1ccccc1n6-c1cccc2ccccc12]

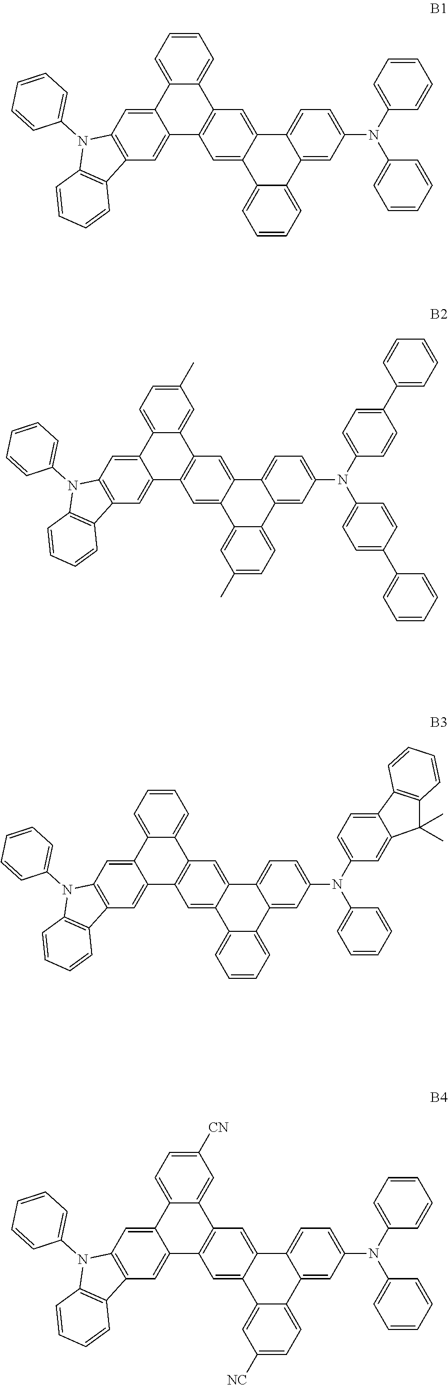 [SMILES: c1ccc(N(c2ccccc2)c2ccc3c(c2)c2ccccc2c2cc4c(cc32)c2ccccc2c2cc3c(cc42)c2ccccc2n3-c2ccccc2)cc1 ; Cc1ccc2c(c1)c1cc3c(cc1c1ccc(N(c4ccc(-c5ccccc5)cc4)c4ccc(-c5ccccc5)cc4)cc21)c1cc(C)ccc1c1cc2c(cc31)c1ccccc1n2-c1ccccc1 ; CC1(C)c2ccccc2-c2ccc(N(c3ccccc3)c3ccc4c(c3)c3ccccc3c3cc5c(cc43)c3ccccc3c3cc4c(cc53)c3ccccc3n4-c3ccccc3)cc21 ; N#Cc1ccc2c(c1)c1cc3c(cc1c1ccc(N(c4ccccc4)c4ccccc4)cc21)c1cc(C#N)ccc1c1cc2c(cc31)c1ccccc1n2-c1ccccc1]

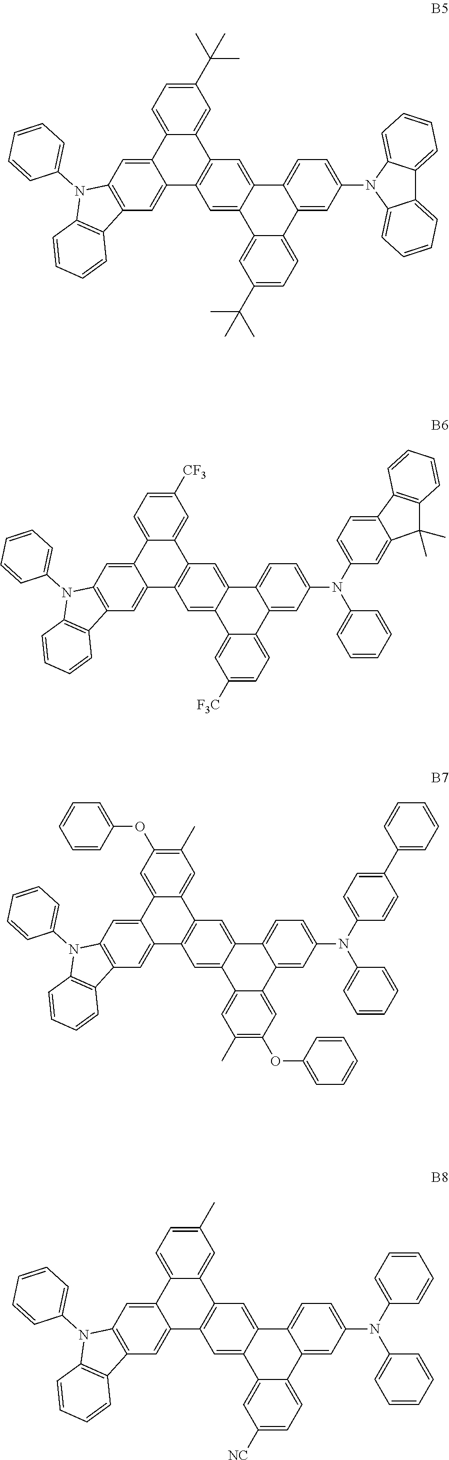 [SMILES: CC(C)(C)c1ccc2c3cc(-n4c5ccccc5c5ccccc54)ccc3c3cc4c5cc(C(C)(C)C)ccc5c5cc6c(cc5c4cc3c2c1)c1ccccc1n6-c1ccccc1 ; CC1(C)c2ccccc2-c2ccc(N(c3ccccc3)c3ccc4c(c3)c3ccc(C(F)(F)F)cc3c3cc5c(cc43)c3cc(C(F)(F)F)ccc3c3cc4c(cc53)c3ccccc3n4-c3ccccc3)cc21 ; Cc1cc2c(cc1Oc1ccccc1)c1cc(N(c3ccccc3)c3ccc(-c4ccccc4)cc3)ccc1c1cc3c4cc(C)c(Oc5ccccc5)cc4c4cc5c(cc4c3cc21)c1ccccc1n5-c1ccccc1 ; Cc1ccc2c(c1)c1cc3c4ccc(N(c5ccccc5)c5ccccc5)cc4c4ccc(C#N)cc4c3cc1c1cc3c4ccccc4n(-c4ccccc4)c3cc21]

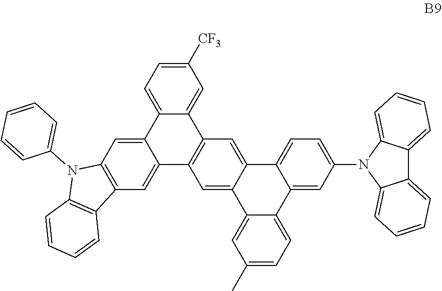 [SMILES: Cc1ccc2c(c1)c1cc3c(cc1c1ccc(-n4c5ccccc5c5ccccc54)cc21)c1cc(C(F)(F)F)ccc1c1cc2c(cc31)c1ccccc1n2-c1ccccc1]

The organic compound according to the embodiment further includes the organic compounds represented by the exemplified compounds of Group C.

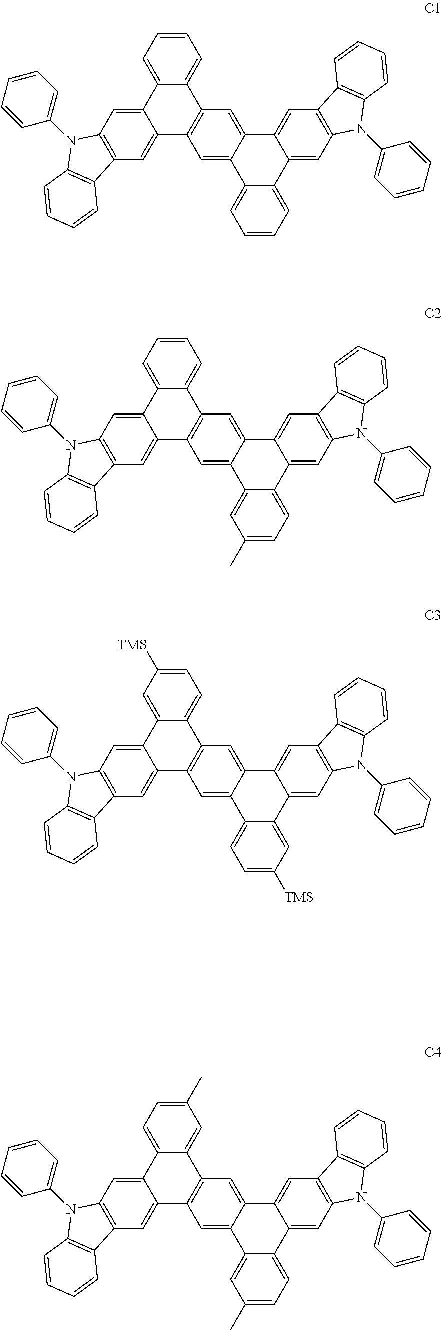 [SMILES: c1ccc(-n2c3ccccc3c3cc4c5cc6c7ccccc7c7cc8c(cc7c6cc5c5ccccc5c4cc32)c2ccccc2n8-c2ccccc2)cc1 ; Cc1ccc2c(c1)c1cc3c(cc1c1cc4c5ccccc5n(-c5ccccc5)c4cc21)c1ccccc1c1cc2c(cc31)c1ccccc1n2-c1ccccc1 ; C[Si](C)(C)c1ccc2c(c1)c1cc3c(cc1c1cc4c5ccc([Si](C)(C)C)cc5c5cc6c(cc5c4cc21)c1ccccc1n6-c1ccccc1)c1ccccc1n3-c1ccccc1 ; Cc1ccc2c(c1)c1cc3c(cc1c1cc4c5ccccc5n(-c5ccccc5)c4cc21)c1cc(C)ccc1c1cc2c(cc31)c1ccccc1n2-c1ccccc1]

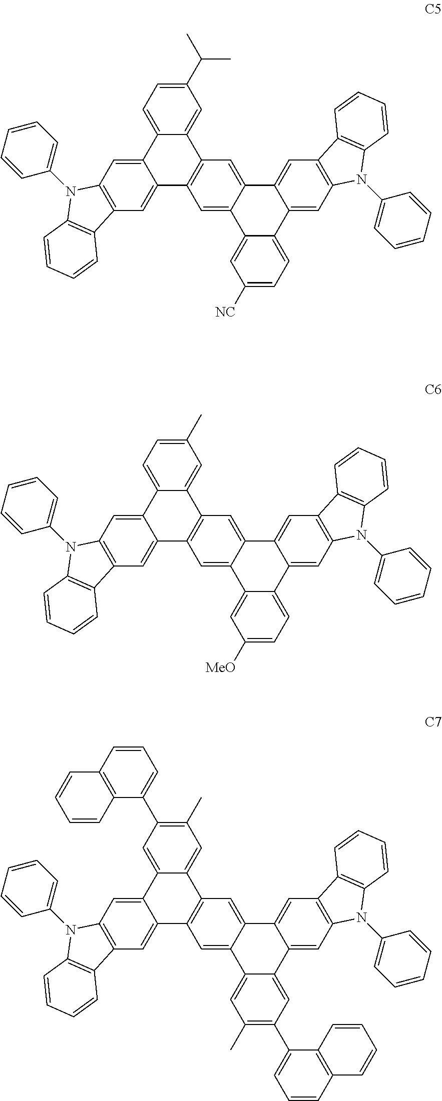 [SMILES: CC(C)c1ccc2c(c1)c1cc3c(cc1c1cc4c5ccccc5n(-c5ccccc5)c4cc21)c1cc(C#N)ccc1c1cc2c(cc31)c1ccccc1n2-c1ccccc1 ; COc1ccc2c(c1)c1cc3c(cc1c1cc4c5ccccc5n(-c5ccccc5)c4cc21)c1cc(C)ccc1c1cc2c(cc31)c1ccccc1n2-c1ccccc1 ; Cc1cc2c(cc1-c1cccc3ccccc13)c1cc3c(cc1c1cc4c5cc(C)c(-c6cccc7ccccc67)cc5c5cc6c(cc5c4cc21)c1ccccc1n6-c1ccccc1)c1ccccc1n3-c1ccccc1]

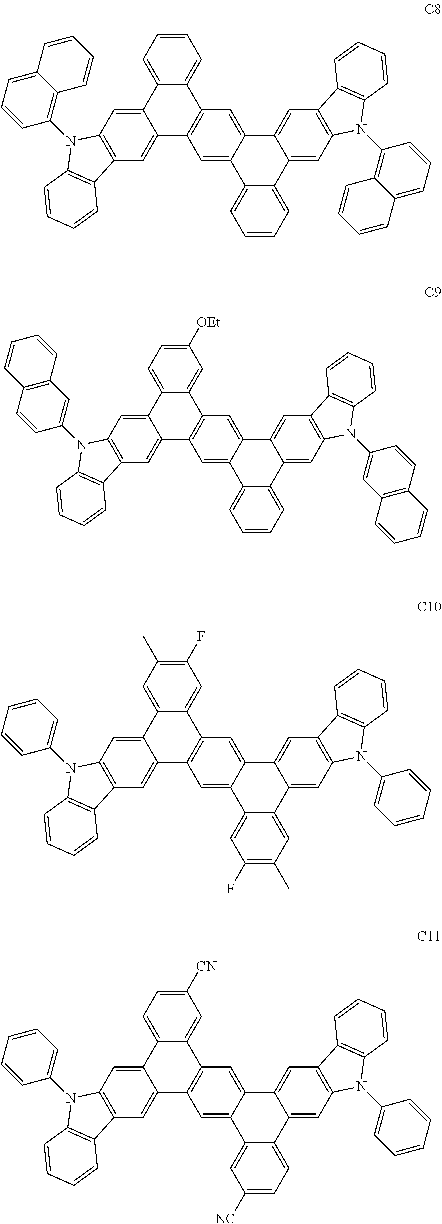 [SMILES: c1ccc2c(-n3c4ccccc4c4cc5c6cc7c8ccccc8c8cc9c(cc8c7cc6c6ccccc6c5cc43)c3ccccc3n9-c3cccc4ccccc34)cccc2c1 ; CCOc1ccc2c(c1)c1cc3c(cc1c1cc4c5ccccc5n(-c5ccc6ccccc6c5)c4cc21)c1ccccc1c1cc2c(cc31)c1ccccc1n2-c1ccc2ccccc2c1 ; Cc1cc2c(cc1F)c1cc3c(cc1c1cc4c5ccccc5n(-c5ccccc5)c4cc21)c1cc(F)c(C)cc1c1cc2c(cc31)c1ccccc1n2-c1ccccc1 ; N#Cc1ccc2c(c1)c1cc3c(cc1c1cc4c5ccccc5n(-c5ccccc5)c4cc21)c1cc(C#N)ccc1c1cc2c(cc31)c1ccccc1n2-c1ccccc1]

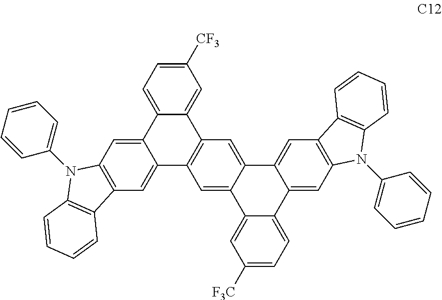 [SMILES: FC(F)(F)c1ccc2c(c1)c1cc3c(cc1c1cc4c5ccccc5n(-c5ccccc5)c4cc21)c1cc(C(F)(F)F)ccc1c1cc2c(cc31)c1ccccc1n2-c1ccccc1]

Among these exemplified compounds, the compounds belonging to Group A, i.e., A1 to A4, has only one arylamine portion per molecule and therefore have a high oxidation potential. That is, the compounds belonging to Group A are stable against oxidation and are useful as a hole transportation material or a host material.

On the other hand, among the above-described exemplified compounds, the compounds belonging to Group B, i.e., B1 to B9, have two different arylamine portions, and the compounds belonging to Group C, i.e., C1 to C12, have two identical arylamine portions. Therefore, the compounds belonging to Group B and the compounds belonging to Group C have a low oxidation potential and high hole mobility and are useful as a hole injection material, a hole transportation material, or a host material. Since the compounds belonging to Group B, having two different arylamine portions, have an asymmetric structure, a compound belonging to Group B requires a synthesis process with more steps than that used for synthesizing a compound belonging to Group C.

The exemplified compounds of Group A, B, and C are represented by Structural Formulae (A), (B), and (C), respectively.

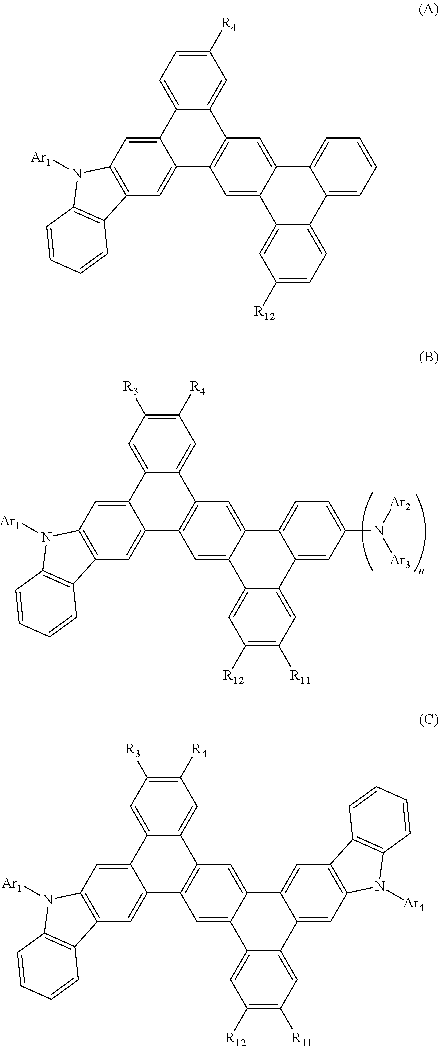

R₃, R₄, R₁₁, and R₁₂ are each independently selected from a hydrogen atom, a halogen atom, an alkyl group, an alkoxy group, and an aryl group. Ar₁ to Ar₄ each represent an aryl group, and n is 1.

The alkyl group, the alkoxy group, and the aryl group may have a substituent.

The substituent is selected from an alkyl group, an aralkyl group, an aryl group, an alkoxy group, a cyano group, and a halogen atom.

The aryl group represented by Ar₁ is, for example, any one of a phenyl group and a naphthyl group.

R₄ and R₁₂ each independently represent, for example, a substituent selected from a hydrogen atom, an isopropyl group, an ethoxy group, a methyl group, a cyano group, a trifluoromethyl group, a methoxy group, and a fluorine atom.

R₃ and R₁₁ each independently represent, for example, a substituent selected from a hydrogen atom, a phenoxy group, a trimethylsilyl group, a naphthyl group, and a methyl group.

### Basic Skeleton

The properties of the basic skeleton of the organic compound according to the embodiment are described with reference to comparative compounds.

The inventors of the present invention suppose that the compounds 1-A and 1-B, which are described in Description of the Related Art, have a poor hole transportation capability because they have a basic skeleton having poor planarity and their molecules are less likely to be orientated in a specific direction. When an organic compound have good molecular planarity, the molecules are likely to overlap with one another and, as a result, the molecules are likely to be orientated in a specific direction. When the molecules are oriented in a specific direction, the area of the overlap of molecular orbitals among the molecules is large. In this case, hopping conduction is likely to occur, which improves the hole transportation capability of the compound. Therefore, the organic compound according to the embodiment preferably has a molecular structure having good planarity that facilitates the orientation of molecules of the organic compound. In this embodiment, a basic skeleton having good planarity preferably has no rotation axis.

All of the organic compounds according to the embodiment, which are represented by Structural Formula (1) or any one of Structural Formulae (A), (B), and (C), have a basic skeleton of 11H-dibenzo[8,9:10,11]tetrapheno[5,6-b]carbazole.

An example of the basic skeleton is 11-phenyl-11H-dibenzo[8,9:10,11]tetrapheno[5,6-b]carbazole represented by Structural Formula (2) below.

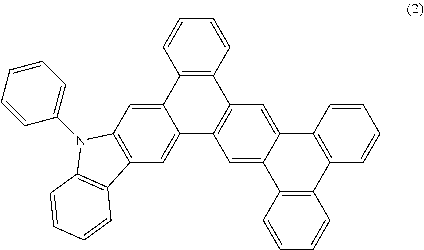 [SMILES: c1ccc(-n2c3ccccc3c3cc4c5cc6c7ccccc7c7ccccc7c6cc5c5ccccc5c4cc32)cc1]

The basic skeleton represented by Structural Formula (2) is compared with the basic skeleton (3) of the compound I-A and the basic skeleton (4) of the compound I-B.

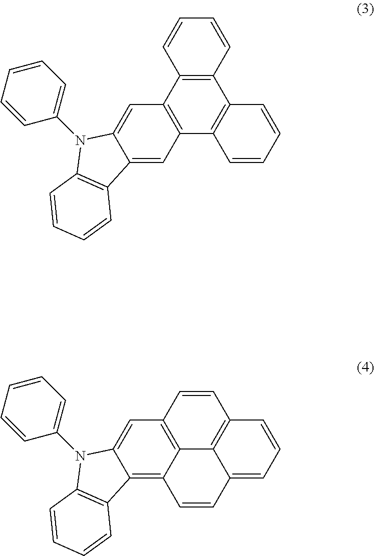 [SMILES: c1ccc(-n2c3ccccc3c3cc4c5ccccc5c5ccccc5c4cc32)cc1 ; c1ccc(-n2c3ccccc3c3c4ccc5cccc6ccc(cc32)c4c65)cc1]

The planarities of the molecular structures were compared with one another by molecular orbital calculation by density functional theory at the B3LYP/6-31G* level. Table 1 shows the results.

The molecular orbital calculation was conducted using Gaussian03 (Gaussian 03, Revision D.01, M. J. Frisch, G. W. Trucks, H. B. Schlegel, G. E. Scuseria, M. A. Robb, J. R. Cheeseman, J. A. Montgomery, Jr., T. Vreven, K. N. Kudin, J. C. Burant, J. M. Millam, S. S. Iyengar, J. Tomasi, V. Barone, B. Mennucci, M. Cossi, G. Scalmani, N. Rega, G. A. Petersson, H. Nakatsuji, M. Hada, M. Ehara, K. Toyota, R. Fukuda, J. Hasegawa, M. Ishida, T. Nakajima, Y. Honda, O. Kitao, H. Nakai, M. Klene, X. Li, J. E. Knox, H. P. Hratchian, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, P. Y. Ayala, K. Morokuma, G. A. Voth, P. Salvador, J. J. Dannenberg, V. G. Zakrzewski, S. Dapprich, A. D. Daniels, M. C. Strain, O. Farkas, D. K. Malick, A. D. Rabuck, K. Raghavachari, J. B. Foresman, J. V. Ortiz, Q. Cui, A. G. Baboul, S. Clifford, J. Cioslowski, B. B. Stefanov, G. Liu, A. Liashenko, P. Piskorz, I. Komaromi, R. L. Martin, D. J. Fox, T. Keith, M. A. Al-Laham, C. Y. Peng, A. Nanayakkara, M. Challacombe, P. M. W. Gill, B. Johnson, W. Chen, M. W. Wong, C. Gonzalez, and J. A. Pople, Gaussian, Inc., Wallingford Conn., 2004) which is widely used today.

TABLE 1

| | | Structural planarity |
|---|---|---|
| | Structural formula | Lx-Ly (Å²) |
| (2) | 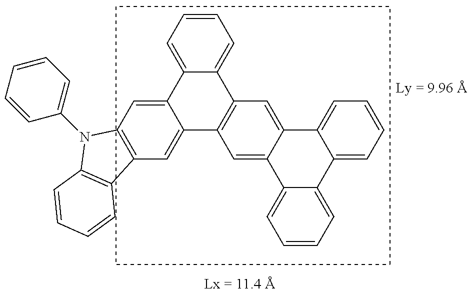 [SMILES: c1ccc(-n2c3ccccc3c3cc4c5cc6c7ccccc7c7ccccc7c6cc5c5ccccc5c4cc32)cc1] | 113.4 |
| (3) | 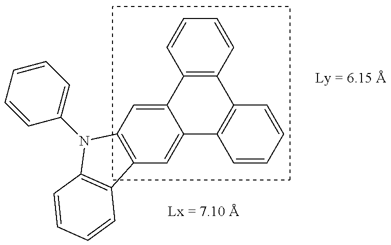 [SMILES: c1ccc(-n2c3ccccc3c3cc4c5ccccc5c5ccccc5c4cc32)cc1] | 43.7 |
| (4) | 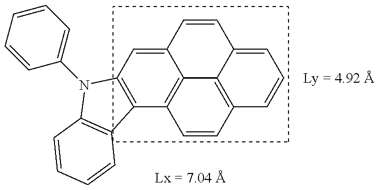 [SMILES: c1ccc(-n2c3ccccc3c3c4ccc5cccc6ccc(cc32)c4c65)cc1] | 34.6 |

The structural portions that differ among the compounds (2), (3), and (4) are shown by dotted rectangles in Table 1. The comparison of the planarities of the molecular shapes was made focusing on the structural portions. The portion of the compound (2) surrounded by the dotted line is a tribenzo[f,k,m]tetraphene skeleton, and the area (Lx·Ly) of the plane formed by the short side of the structural portion (length: Ly) and the long side of the structural portion (length: Lx) is 113.4 Å². The larger the value of Lx·Ly, the better the planarity of the molecular structure. In a similar manner, the portion of the compound (3) surrounded by the dotted line is a triphenylene skeleton, and Lx·Ly thereof is 43.7 Å². The portion of the compound (4) surrounded by the dotted line is a pyrene skeleton, and Lx·Ly thereof is 34.6 Å². Thus, the compound (2) has a larger Lx·Ly and better planarity than the compounds (3) and (4). Therefore, the molecules of the compound (2) are likely to be oriented in a substrate direction and thus realizes a good hole transportation capability.

The organic compounds according to the embodiment including the compound (2) as a basic skeleton, which are represented by Structural Formula (1) or any one of Structural Formulae (A), (B), and (C), have a good hole transportation capability since molecules of the organic compound are likely to be oriented in a specific direction. Therefore, when the organic compound according to the embodiment is used for producing an organic light-emitting device, the driving voltage of the organic light-emitting device may be reduced.

As described above, the organic compound according to the embodiment, having 11H-dibenzo[8,9:10,11]tetrapheno[5,6-b]carbazole as a basic skeleton, has a good hole transportation capability. Therefore, when the organic compound according to the embodiment is used for producing an organic light-emitting device, the driving voltage of the organic light-emitting device may be reduced.

The inventors of the present invention consider that molecules of the organic compound according to the embodiment are likely to be oriented in a specific direction because the organic compound has the above-described basic skeleton.

The thin film may be formed by a publicly known method such as vacuum deposition, spin coating, or casting.

Then, the organic light-emitting device according to the embodiment is described.

The organic light-emitting device according to the embodiment includes a pair of electrodes, that is, an anode and a cathode, and an organic compound layer interposed between the electrodes. In the organic light-emitting device according to the embodiment, the organic compound layer may be a single layer or a multilayered body constituted by a plurality of sublayers as long as the organic compound layer includes a light-emitting layer.

When the organic compound layer is a multilayered body constituted by a plurality of sublayers, the organic compound layer may further include a hole injection layer, a hole transportation layer, an electron-blocking layer, a hole-exciton-blocking layer, an electron transportation layer, an electron injection layer, and the like. The light-emitting layer may be a single layer or a multilayered body constituted by a plurality of sublayers.

In organic light-emitting device according to the embodiment, at least one sublayer constituting the organic compound layer includes the organic compound according to the embodiment. Specifically, one or more layers selected from the above-described light-emitting layer, hole injection layer, hole transportation layer, electron-blocking layer, light-emitting layer, hole-exciton-blocking layer, electron transportation layer, electron injection layer, and the like include the organic compound according to the embodiment. It is preferable that the hole transportation layer includes the organic compound according to the embodiment.

In the organic light-emitting device according to the embodiment, when the light-emitting layer includes the organic compound according to the embodiment, the light-emitting layer may be composed of only the organic compound according to the embodiment or may be composed of the organic compound according to the embodiment and other compounds. When the light-emitting layer is composed of the organic compound according to the embodiment and other compounds, the organic compound according to the embodiment may serve as a host of the light-emitting layer or a guest of the light-emitting layer. In another case, the organic compound according to the embodiment may serve as an assist material, which may be included in the light-emitting layer.

When the organic light-emitting device according to the embodiment is provided as a multicolored light-emitting device such as a white light-emitting device, the light-emitting layer may be a single layer or may be constituted by a plurality of sublayers. The plurality of sublayers may be a plurality of light-emitting layers, i.e., two or more light-emitting layers, stacked on top of one another between the anode and the cathode. In another case, the plurality of sublayers may be a plurality of light-emitting layers that are arranged in the in-plane direction of a substrate including the multicolored light-emitting device.

The term “host” used herein refers to a compound having the highest weight ratio among compounds constituting the light-emitting layer. The term “guest” used herein refers to a compound that has a lower weight ratio than the host among the compounds constituting the light-emitting layer and that is mainly responsible for emitting light. The term “assist material” used herein refers to a compound that has a lower weight ratio than the host among the compounds constituting the light-emitting layer and that assists the guest in emitting light. The assist material is also called “the second host”.

The inventors of the present invention have conducted various studies and found that, by using the organic compound according to the embodiment as a material of the hole transportation layer, a light-emitting device capable of emitting light with high efficiency, a high luminance, and markedly high durability may be produced. The hole transportation layer may be a single layer or constituted by a plurality of sublayers. The expression “a plurality of sublayers” refers to the state in which an organic layer having a hole transportation capability and another organic layer having a hole transportation capability are stacked on top of one another. In this case, the color of light emitted by the organic light-emitting device is not particularly limited. Specifically, the color of light emitted by the organic light-emitting device may be white or a moderate color.

Film deposition may be conducted by vapor deposition or coating.

A low-molecular-weight or high-molecular-weight organic compound may be used in combination with the organic compound according to the embodiment. A low-molecular-weight or high-molecular-weight organic compound may be used as a compound having a hole injection capability, a compound having a hole transportation capability, a compound serving as a host, a luminescent compound, a compound having an electron injection capability, or a compound having an electron transportation capability.

Examples of these compounds are shown below.

A material having high hole mobility may be used as the compound having a hole injection capability or the compound having a hole transportation capability. Examples of a low-molecular-weight or high-molecular-weight material having a hole injection capability or a hole transportation capability include, but are not limited to, a triarylamine derivative, a phenylenediamine derivative, a stilbene derivative, a phtalocyanine derivative, a porphyrin derivative, polyvinylcarbazole, polythiophene, and other conductive polymers.

Examples of the host include, but are not limited to, condensed-ring compounds (e.g., a fluorene derivative, a naphthalene derivative, an anthracene derivative, a pyrene derivative, a carbazole derivative, a quinoxaline derivative, and a quinoline derivative), organoaluminium complexes such as tris(8-quinolinolato)aluminium, organozinc complexes, and polymer derivatives such as a triphenylamine derivative, a polyfluorene derivative, and a polyphenylene derivative.

A compound having an electron injection capability and a compound having an electron transportation capability are appropriately selected with consideration of, for example, the balance with the hole mobility of the compound having a hole injection capability and the compound having a hole transportation capability. Examples of the compound having an electron injection capability or the compound having an electron transportation capability include, but are not limited to, an oxadiazole derivative, an oxazole derivative, a pyrazine derivative, a triazole derivative, a triazine derivative, a quinoline derivative, a quinoxaline derivative, a phenanthroline derivative, and an organoaluminium complex.

The higher the work function of a conductive body is, the more the conductive body is useful as a material of the anode. Examples of such a conductive body include single-element metals such as gold, platinum, silver, copper, nickel, palladium, cobalt, selenium, vanadium, and tungsten; alloys containing two or more of these single-element metals; and metal oxides such as stannic oxide, zinc oxide, indium oxide, indium tin oxide (ITO), and indium zinc oxide. Alternatively, conductive polymers such as polyaniline, polypyrrole, and polythiophene may also be used. The above-described electrode substance may be used alone or in combination of two or more. The anode may have a single-layer structure or a multilayered structure.

In contrast, the lower the work function of a conductive body is, the more the conductive body is useful as a material of the cathode. Examples of such a conductive body include single-element metals such as alkali metals (e.g., lithium), alkaline-earth metals (e.g., calcium), aluminium, titanium, manganese, silver, lead, and chromium. Alternatively, alloys containing two or more of these single-element metals may also be used, and example of the alloys include a magnesium-silver alloy, an aluminium-lithium alloy, and an aluminium-magnesium alloy. In another case, metal oxides such as indium tin oxide (ITO) may also be used. The above-described electrode substance may be used alone or in combination of two or more. The cathode may have a single-layer structure or a multilayered structure.

In the organic light-emitting device according to the embodiment, a layer including the organic compound according to the embodiment and a layer including another organic compound may be formed as follows. Generally, a thin film is formed by vacuum deposition, ionized deposition, sputtering, or plasma. Alternatively, the organic compound may be dissolved in an appropriate solvent and a publicly known coating method (e.g., spin coating, dipping, casting, a Langmuir-Blodgett (LB) method, or an inkjet method) may be employed. When vacuum deposition, solution coating, or the like is employed to form a film, crystallization and the like are less likely to occur and the film has good temporal stability. When coating is employed to form a film, the organic compound may be used in combination with an appropriate binder resin to form a film.

Examples of the binder resin include, but are not limited to, a polyvinylcarbazole resin, a polycarbonate resin, a polyester resin, an acrylonitrile-butadiene-styrene (ABS) resin, an acrylic resin, a polyimide resin, a phenolic resin, an epoxy resin, a silicone resin, and a urea resin. These binder resins may be used alone as a homopolymer or a copolymer or in mixture of two or more. As needed, publicly known additives such as a plasticizer, an antioxidant, and an UV absorber may be used in combination with the binder resin.

The organic light-emitting device according to the embodiment may be used as a component of a display apparatus or a lighting apparatus. Other applications of the organic light-emitting device according to the embodiment include an exposure light source of an electrophotographic image-forming apparatus, a backlight of a liquid crystal display apparatus, a color-filter-less white light source, and a light-emitting apparatus including a color filter and a white light source. The electrophotographic image-forming apparatus includes an exposure light source and a photosensitive member, and examples thereof include a copying machine and a laser beam printer. The photosensitive member is exposed to light on the basis of the light-emission state or non-light-emission state of a plurality of organic light-emitting devices included in the exposure light source, and thereby a latent image is formed on the photosensitive member. The light-emission state and the non-light-emission state of each organic light-emitting device are controlled by the corresponding switching device. The exposure light source includes the plurality of organic light-emitting devices, which are arranged in a line in the longitudinal direction of the photosensitive member. Since the organic light-emitting devices arranged in a line are disposed in the vicinity of the photosensitive member, the size of the image-forming apparatus may be reduced.

The color filter is a filter though which at least any one of red, green, and blue lights is transmitted. The light-emitting apparatus may include a filter used for control the chromaticity of white in combination with a white light source.

The display apparatus includes the organic light-emitting device according to the embodiment in its display section. The display section includes a plurality of pixels, which each include the organic light-emitting device according to the embodiment and a transistor, which is an example of a switching device or an amplification device used for controlling emission luminance. The anode or cathode of the organic light-emitting device is electrically connected to the drain electrode or source electrode of the transistor. The display apparatus may be used in an image display system such as PC. The display apparatus may optionally further include a color filter.

The display apparatus may be used in an image display system including an input section in which image information is received from an area CCD, a linear CCD, a memory card, or the like and a display section in which the received image is output. The display apparatus may be used in a display section included in an image-pickup apparatus or an ink jet printer, which has both the image-output function of displaying externally inputted image information and the input function of serving as an operation panel that receives information for editing the image. The display apparatus may be used in a display section of a multifunction printer.

The lighting apparatus is an apparatus used for lighting an interior or the like. The lighting apparatus may emit white light (including neutral white light) or light of any color from blue to red. The lighting apparatus may include the organic light-emitting device according to the embodiment and an inverter circuit connected to the organic light-emitting device. The term “white light” used herein refers to light having a color temperature of 4,200 K, and the term “neutral white light” used herein refers to light having a color temperature of 5,000 K. The lighting apparatus may further include a color filter.

Other applications of the organic compound according to the embodiment include an organic solar cell, an organic thin-film transistor (TFT), a luminescence material used for recognition of organisms or the like, a film, and a filter.

Next, a display apparatus including the organic light-emitting device according to the embodiment is described with reference to FIGURE.

FIGURE is a schematic cross-sectional view of an example of a display apparatus including the organic light-emitting device according to the embodiment and a TFT device, which is an example of a transistor, connected to the organic light-emitting device. FIGURE shows a display apparatus 20 including two sets of the organic light-emitting device and the TFT device. The structure of the display apparatus 20 is described in detail below.

In FIGURE, the display apparatus 20 includes a substrate 1 composed of glass or the like; a protection film 2 deposited on or above the substrate 1 which has moisture resistance in order to protect the TFT device or an organic compound layer; a gate electrode 3 composed of a metal; a gate insulation film 4; and a semiconductor layer 5.

The TFT device 8 includes the semiconductor layer 5, a drain electrode 6, and a source electrode 7. An insulation film 9 is deposited on or above the TFT device 8. The source electrode 7 is connected to an anode 11 of the organic light-emitting device through a contact hole 10. The structure of the display apparatus is not limited to the above-described structure as long as any one of the anode and the cathode is connected to any one of the source electrode and the drain electrode of the TFT device.

In the display apparatus 20 shown in FIGURE, an organic compound layer 12, which may be a single layer or may be constituted by a plurality of sublayers, is illustrated as a single layer. A first protection layer 14 and a second protection layer 15 are deposited on or above a cathode 13 in order to suppress degradation of the organic light-emitting device.

In the display apparatus according to the embodiment, a metal-insulator-metal (MIM) device may be used as a switching device instead of a transistor. The type of transistor is not limited to a transistor including a single crystal silicon wafer. Alternatively, a thin-film transistor including an active layer formed on an insulated surface of the substrate may also be used. A thin-film transistor including an active layer composed of single-crystal silicon, a thin-film transistor including an active layer composed of non-single-crystalline silicon such as amorphous silicon or microcrystalline silicon, and a thin-film transistor including an active layer that is a non-single-crystal oxide semiconductor such as indium zinc oxide (IZO) or indium gallium zinc oxide (IGZO) may also be used. A thin-film transistor is also referred to as TFT device.

### EXAMPLES

The present invention is described with reference to examples, which do not limit the present invention.

### Example 1

### Synthesis of Exemplified Compound A1

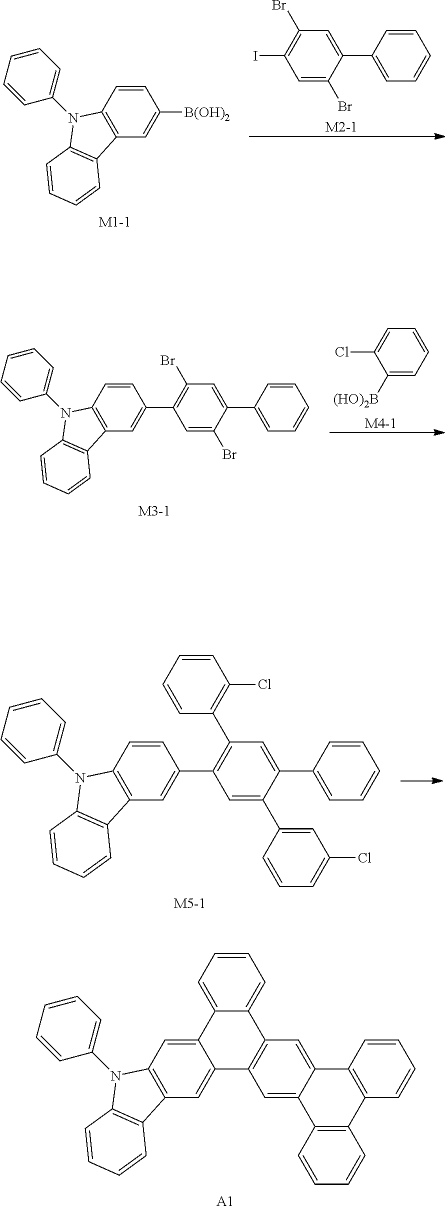

### (1) Synthesis of Intermediate M3-1

Into a 200-ml eggplant flask, 2.21 g (7.7 mmol) of (9-phenyl-9H-carbazole-3-yl)boronic acid, 2.70 g (6.16 mmol) of 2,5-dibromo-4-iodo-1,1′-biphenyl, 0.07 g of Pd(PPh₃)₄, 30 ml of toluene, 15 ml of ethanol, and 30 ml of 2M-aqueous sodium carbonate solution were charged. The resulting reaction solution was stirred for 5 hours under nitrogen flow while being heated at 80° C. After the reaction was completed, water was added in the reaction solution, and washing and extraction were performed. Then, the resulting extract was purified by silica gel column chromatography using chlorobenzene. Subsequently, recrystallization was performed with methanol. Thus, 1.5 g (yield: 36%) of a white solid was obtained.

### (2) Synthesis of Intermediate M5-1

Into a 100-ml eggplant flask, 0.5 g (1.14 mmol) of Intermediate M3-1, 0.54 g (3.43 mmol) of (2-chlorophenyl)boronic acid, 0.066 g of Pd(PPh₃)₄, 50 ml of xylene, 25 ml of ethanol, and 50 ml of 4M-aqueous sodium carbonate solution were charged. The resulting reaction solution was refluxed for 5 hours under nitrogen flow while being heated. After the reaction was completed, extraction and condensation were performed using chloroform and water. The resulting extract was purified by silica gel column chromatography using chlorobenzene. Then, dispersion washing was performed using methanol. Thus, 0.55 g (yield: 78.2%) of a white solid was obtained.

### (3) Synthesis of Exemplified Compound A1

Into a 50-ml reaction container, 0.5 g (0.81 mmol) of Intermediate M5-1, 0.29 g of palladium acetate, 0.97 g of P(Cy)₃HBF₄, 1.9 g of potassium carbonate, and 21 ml of dimethylacetamide were charged. The resulting reaction solution was refluxed for 7 hours under nitrogen flow while being heated. After the reaction was completed, methanol and water were added in the reaction solution, and the precipitated solid was collected by filtering. The precipitated solid was purified by silica gel column chromatography using chlorobenzene, and the resulting solid was recrystallized using o-xylene. Thus, 0.24 g (yield: 54.2%) of Exemplified Compound A1 was prepared.

The purity of Exemplified Compound A1 determined by high-performance liquid chromatography (HPLC) was 99% or more.

Mass spectrometry was conducted using a matrix assisted laser desorption/ionization-time of flight mass spectrometer (MALDI-TOF-MS) “Autoflex LRF” produced by Bruker Corporation.

### [MALDI-TOF-MS]

Observed value: m/z=543.48

Calculated value: C₄₂H₂₅N=543.65

Then, a silicon substrate that has been subjected to ultrasonic cleaning with pure water, acetone, and isopropyl alcohol was placed on a vacuum deposition apparatus. Vapor deposition of Exemplified Compound A1 was performed at a vapor deposition rate of 1.0 nm/sec under a vacuum of 4×10⁻⁵ Pa to form a thin film having a thickness of 50 nm. Ellipsometric parameters of the thin film were measured using a variable angle spectroscopic ellipsometer (produced by J. A. Woollam Co. Inc.) with an incidence angle of 45° to 75° at intervals of 5° and a wavelength of 200 to 1,000 nm. The resulting data were analyzed using an analytical software “WVASE32” produced by J. A. Woollam Co. Inc., and the order parameter S was calculated on the basis of the relationship between Kₑ and Kₒ. As a result, it was confirmed that the order parameter S of Exemplified Compound A1 was S=−0.22 and the molecular plane of Exemplified Compound A1 was oriented in a direction parallel to the substrate.

### Example 2

### Synthesis of Exemplified Compound B3

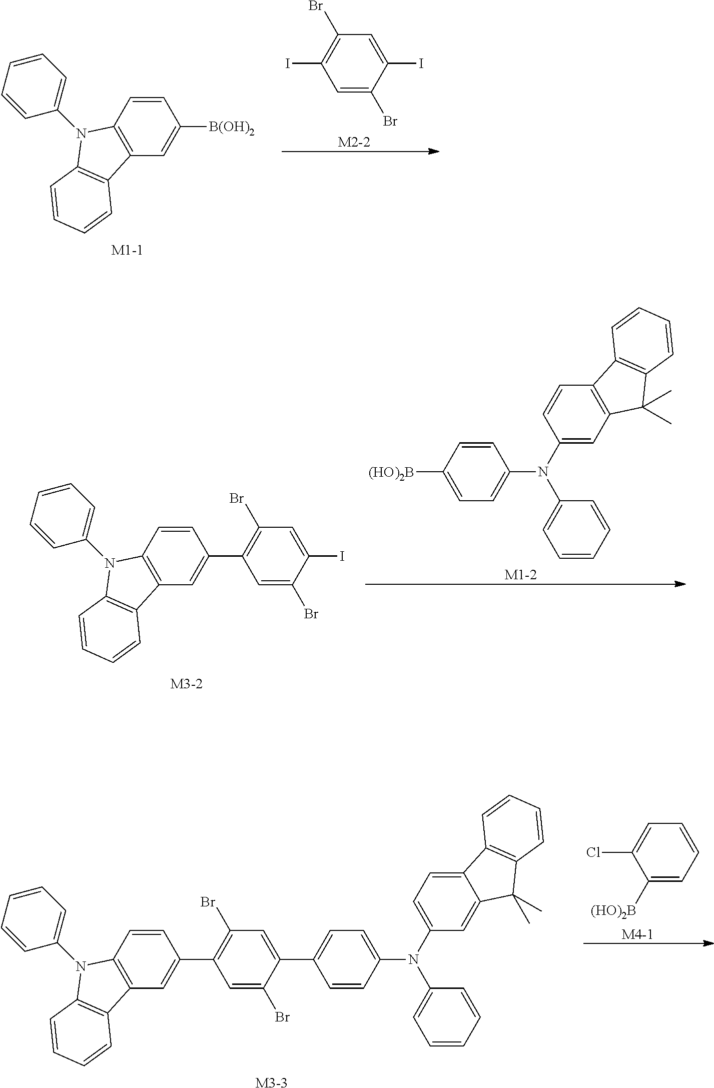

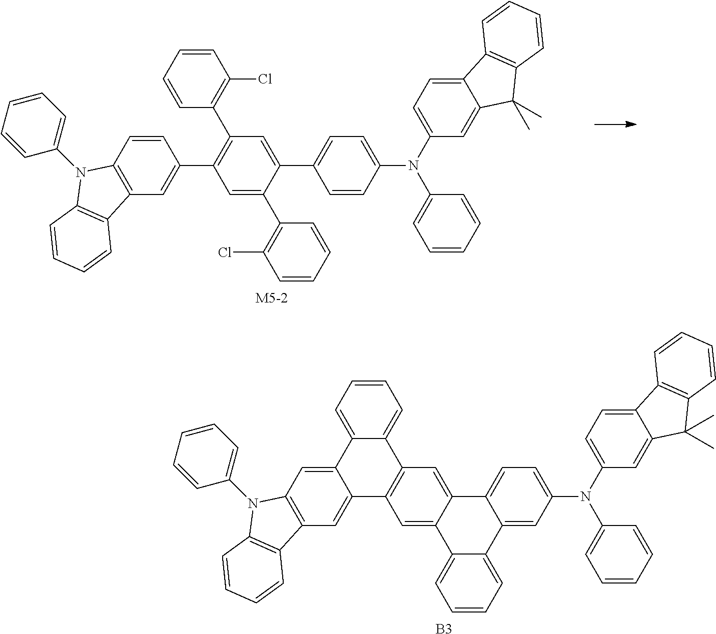

### (1) Synthesis of Intermediate M3-2

Into a 200-ml eggplant flask, 2 g (7.0 mmol) of (9-phenyl-9H-carbazole-3-yl)boronic acid, 3.40 g (7.0 mmol) of 1,4-dibromo-2,5-diiodobenzene, 0.40 g of Pd(PPh₃)₄, 40 ml of toluene, 20 ml of ethanol, 40 ml of 2M-aqueous sodium carbonate solution were charged. The resulting reaction solution was stirred for 4 hours under nitrogen flow while being heated at 80° C. After the reaction was completed, water was added in the reaction solution, and washing and extraction were performed. Then, the resulting extract was purified by silica gel column chromatography using chlorobenzene. Subsequently, recrystallization was performed with methanol. Thus, 2.18 g (yield: 52%) of a white solid was obtained.

### (2) Synthesis of Intermediate M3-3

Intermediate M3-3 was obtained as in Synthesis of Intermediate M3-2 except that (9-phenyl-9H-carbazole-3-yl)boronic acid and 1,4-dibromo-2,5-diiodobenzene used therein were replaced by Intermediate M1-2 and Intermediate M3-2, respectively.

### (3) Synthesis of Intermediate M5-2

Into a 100-ml eggplant flask, 0.5 g (0.60 mmol) of Intermediate M3-3, 0.37 g (2.39 mmol) of (2-chlorophenyl)boronic acid, 0.069 g of Pd(PPh₃)₄, 20 ml of xylene, 10 ml of ethanol, and 20 ml of 4M-aqueous sodium carbonate solution were charged. The resulting reaction solution was refluxed for 5 hours under nitrogen flow while being heated. After the reaction was completed, extraction and condensation were performed using chloroform and water. The resulting extract was purified by silica gel column chromatography using chlorobenzene. Then, dispersion washing was performed using methanol. Thus, 0.39 g (yield: 72.8%) of a white solid was obtained.

### (4) Synthesis of Exemplified Compound B3

Exemplified Compound B3 was prepared as in (3) Synthesis of Exemplified Compound A1 of Example 1 except that Intermediate M5-1 used therein was replaced by Intermediate M5-2.

### [MALDI-TOF-MS]

Observed value: m/z=826.96

Calculated value: C₅₄H₃₂N₂=827.02

The order parameter S of Exemplified Compound B3 determined as in Example 1 was S=−0.25.

### Example 3

### Synthesis of Exemplified Compound C1

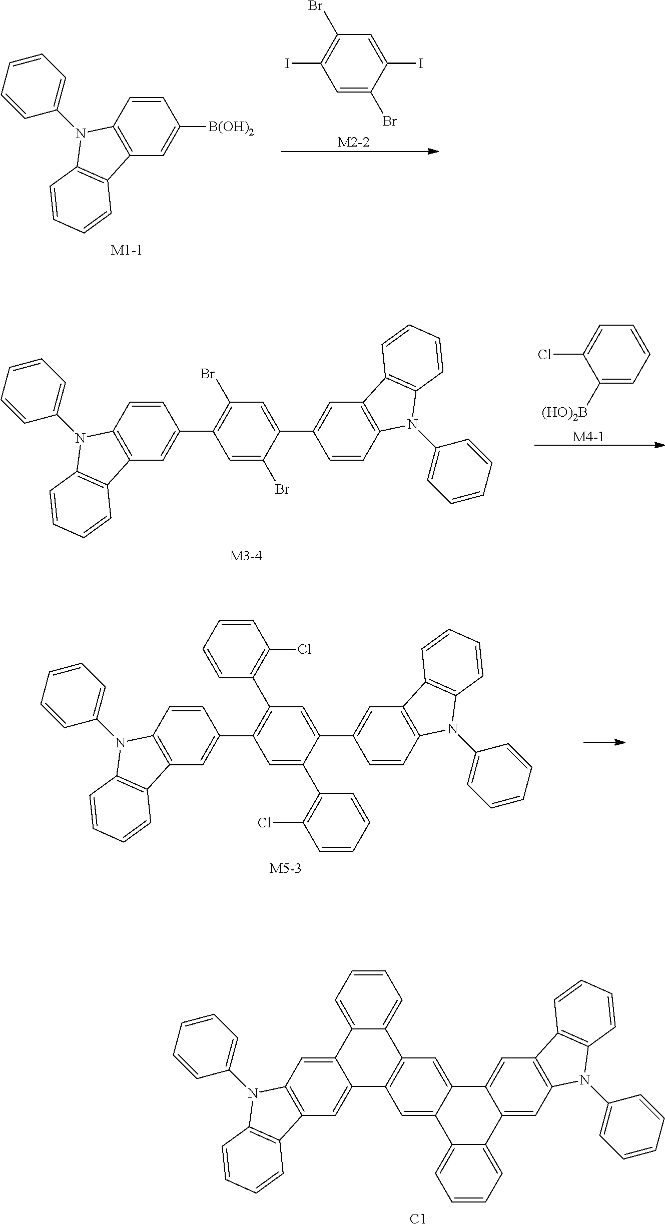

### (1) Synthesis of Intermediate M3-4

Into a 200-ml eggplant flask, 2 g (7.0 mmol) of (9-phenyl-9H-carbazole-3-yl)boronic acid, 1.36 g (2.79 mmol) of 1,4-dibromo-2,5-diiodobenzene, 0.03 g of Pd(PPh₃)₄, 30 ml of toluene, 15 ml of ethanol, and 30 ml of 2M-aqueous sodium carbonate solution were charged.

The resulting reaction solution was stirred for 6 hours under nitrogen flow while being heated at 80° C. After the reaction was completed, water was added in the reaction solution, and washing and extraction were performed. Then, the resulting extract was purified by silica gel column chromatography using chlorobenzene. Subsequently, recrystallization was performed with methanol. Thus, 0.78 g (yield: 39%) of a white solid was obtained.

### (2) Synthesis of Intermediate M5-3

Intermediate M5-3 was obtained as in (3) Synthesis of Intermediate M5-2 of Example 2 except that Intermediate M3-3 used therein was replaced by Intermediate M3-4.

### (3) Synthesis of Exemplified Compound C1

Exemplified Compound C1 was prepared as in (3) Synthesis of Exemplified Compound A1 of Example 1 except that Intermediate M5-1 used therein was replaced by Intermediate M5-3.

### [MALDI-TOF-MS]

Observed value: m/z=708.80

Calculated value: C₆₃H₄₂N₂=708.85

The order parameter S of Exemplified Compound C1 determined as in Example 1 was S=−0.27.

### Comparative Example 1

Determination of order parameter S of 4,4′-bis[N-(1-naphthyl)-N-phenyl]biphenyl (hereinafter, abbreviated as “NPD”), which is commonly used as a hole transport material of a organic light-emitting device

The order parameter S of NPD determined as in Example 1 was S=−0.02. Thus, it was confirmed that NPD molecules were randomly arranged in the thin film.

### Example 4

In Example 4, an organic light-emitting device including an anode, a hole injection layer, a hole transportation layer, a light-emitting layer, a hole-exciton-blocking layer, an electron transportation layer, and a cathode, which were sequentially stacked on or above a substrate, was prepared. A part of materials used in Example 4 are described below.

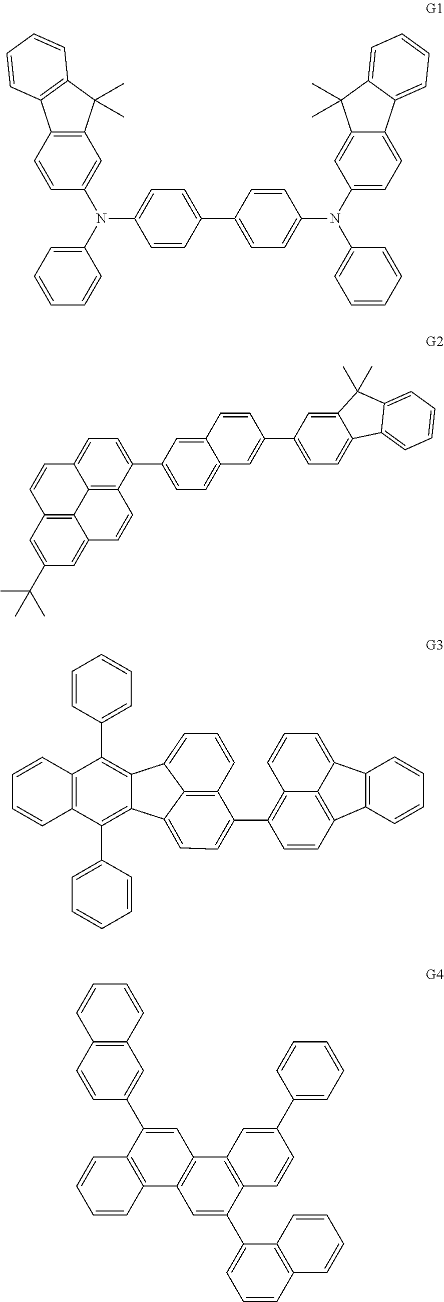

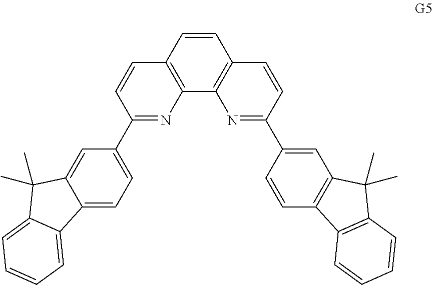

An ITO film was deposited on a glass substrate, and a desired pattern was formed in the ITO film. Thus, an ITO electrode (anode) was formed. The thickness of the ITO electrode was set to 100 nm. The substrate on which an ITO electrode was formed was used as an ITO substrate in the following process.

The organic compound layers and electrode layers shown in Table 2 were sequentially deposited on or above the ITO substrate. The areas of the electrodes facing the anode, that is, the metal electrode layers serving as a cathode, were set to 3 mm². Table 2 shows the material and thickness of each layer.

TABLE 2

| | | Thickness |
|---|---|---|
| | Material | (nm) |
| Hole injection layer | G1 | 40 |
| Hole transportation layer | Exemplified Compound A1 | 10 |
| Light-emitting layer | G2 (host) G3 (guest) | 30 |
| | G2:G3 = 95:5 (weight ratio) | |
| Hole-blocking layer | G4 | 10 |
| Electron transportation layer | G5 | 30 |
| First metal electrode layer | LiF | 1 |
| Second metal electrode layer | Al | 100 |

The characteristics of the prepared light-emitting device were determined and evaluated. It was observed that, upon a voltage of 5.9 V was applied between the ITO electrode serving as a positive electrode and the Al electrode serving as a negative electrode, the light-emitting device emitted blue light having a luminance of 2,000 cd/m² at a luminous efficiency of 8.8 cd/A. The maximum emission wavelength of the light-emitting device was 460 nm and the chromaticity of light emitted by the light-emitting device was (X, Y)=(0.16, 0.24). In order to evaluate the stability of the light-emitting device, the service life of the light-emitting device, that is, a time during which the luminance is reduced by 50% when the light-emitting device is driven at an initial luminance of 10,000 cd/m², was measured. The service life was over 700 hours. The equipment used for the measurement was specifically as follows. The current-voltage characteristics of the light-emitting device were determined using a microammeter “4140B” produced by Hewlett-Packard Development Company, L.P. The emission luminance of the light-emitting device was determined using “BM7” produced by TOPCON CORPORATION. Table 3 shows the results.

### Examples 5 to 12

An organic light-emitting device was prepared as in Example 4 except that the hole transportation layer and the host used in Example 4 were each changed to any one of the compounds according to the embodiment as shown in Table 3. The characteristics of the prepared light-emitting device were determined and evaluated as in Example 4. Table 3 shows the results.

TABLE 3

| | Hole | | Luminous | | 50%-Reduction |
|---|---|---|---|---|---|
| | transportation | | efficiency | Voltage | service life |
| | layer | Host | (cd/A) | (V) | (h) |
| Example 4 | A1 | G3 | 8.8 | 5.9 | 700 |
| Example 5 | A4 | G3 | 9.0 | 5.8 | 550 |
| Example 6 | B3 | G3 | 9.7 | 5.2 | 600 |
| Example 7 | B4 | G3 | 9.6 | 5.1 | 600 |
| Example 8 | C1 | G3 | 9.8 | 5.0 | 650 |
| Example 9 | C9 | G3 | 9.7 | 5.3 | 500 |
| Example | C12 | G3 | 9.6 | 5.2 | 600 |
| 10 | | | | | |
| Example | C1 | A1 | 9.9 | 4.9 | 400 |
| 11 | | | | | |
| Example | C1 | A4 | 9.8 | 4.7 | 450 |
| 12 | | | | | |

### RESULT AND CONSIDERATION

As described above, by using the novel condensed-ring compound according to the embodiment as a material of the hole transportation layer, a material of the light-emitting layer, or, in particular, a host, an organic light-emitting device that has a long service life and is capable of driving at a low voltage may be provided.

The organic compound according to the embodiment realizes high degree of orientation and a good hole transportation capability. Therefore, by using the organic compound according to the embodiment as a component of an organic light-emitting device, an organic light-emitting device having a good light-emitting property may be provided.

As described above with reference to preferred embodiments and examples, an organic compound having a good hole transportation capability may be provided. Thus, an organic light-emitting device capable of driving at a low voltage may be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-096001, filed Apr. 30, 2013 and Japanese Patent Application No. 2014-044266, filed Mar. 6, 2014 which are hereby incorporated by reference herein in their entirety.

What is claimed is:

1. An organic compound represented by Structural Formula (1), 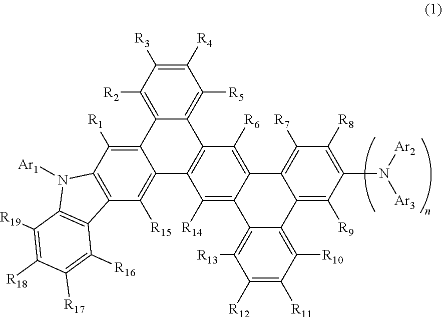
where R₁ to R₁₉ are each independently selected from a hydrogen atom, a halogen atom, an alkyl group, an alkoxy group, and an aryl group; Ar₁ to Ar₃ each represent an aryl group; n is 0 or 1;
the alkyl group, the alkoxy group, the aryl group may include a substituent;
the substituent is selected from an alkyl group, an aralkyl group, an aryl group, an alkoxy group, a cyano group, and a halogen atom; and
when n is 0, an 11H-dibenzo[8,9:10,11]tetrapheno[5,6-b]carbazole skeleton shown in Structural Formula (1) includes a hydrogen atom.

2. An organic compound represented by any one of Structural Formulae (A), (B), and (C), 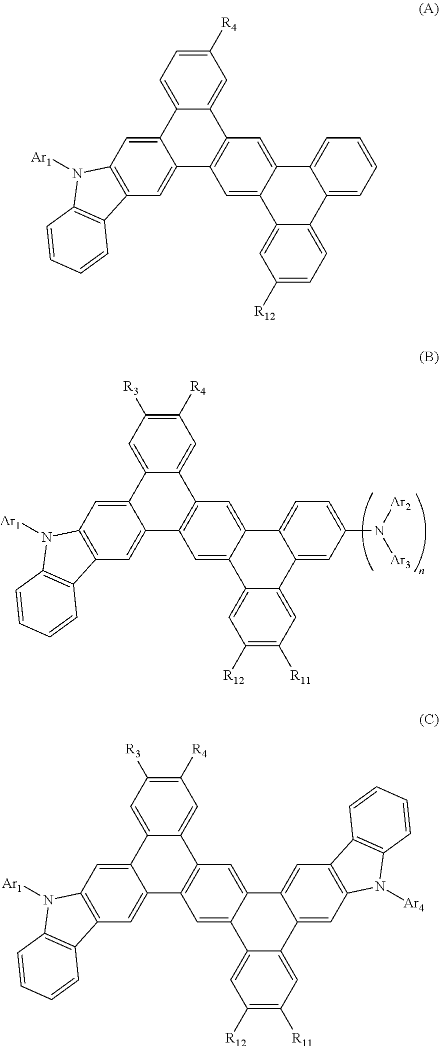
where R₃, R₄, R₁₁, and R₁₂ are each independently selected from a hydrogen atom, a halogen atom, an alkyl group, an alkoxy group, and an aryl group; Ar₁ to Ar₄ each represent an aryl group; n is 1;
the alkyl group, the alkoxy group, and the aryl group may include a substituent; and
the substituent is selected from an alkyl group, an aralkyl group, an aryl group, an alkoxy group, a cyano group, and a halogen atom.

3. The organic compound according to claim 2,
wherein the aryl group represented by Ar₁ is any one of a phenyl group and a naphthyl group.

4. The organic compound according to claim 2,
wherein R₄ and R₁₂ are substituents each independently selected from a hydrogen atom, an isopropyl group, an ethoxy group, a methyl group, a cyano group, a trifluoromethyl group, a methoxy group, and a fluorine atom.

5. The organic compound according to claim 2,
wherein R₃ and R₁₁ are substituents each independently selected from a hydrogen atom, a phenoxy group, a trimethylsilyl group, a naphthyl group, and a methyl group.

6. An organic light-emitting device comprising:
an anode;
a cathode; and
an organic compound layer interposed between the anode and the cathode,
wherein the organic compound layer includes the organic compound according to claim 2.

7. The organic light-emitting device according to claim 6,
wherein the organic compound layer serves as a light-emitting layer.

8. The organic light-emitting device according to claim 6,
wherein the organic compound layer serves as a hole transportation layer; and
wherein the organic light-emitting device further comprises a light-emitting layer.

9. The organic light-emitting device according to claim 7,
wherein the light-emitting layer is constituted by two or more light-emitting sublayers stacked on top of one another, the two or more light-emitting sublayers emitting light of different colors.

10. The organic light-emitting device according to claim 9 that emits white light.

11. A display apparatus comprising a plurality of pixels, the plurality of pixels each including:
the organic light-emitting device according to claim 6; and
a transistor connected to the organic light-emitting device.

12. A display apparatus comprising a plurality of pixels, the plurality of pixels each including:
the organic light-emitting device according to claim 6;
a transistor connected to the organic light-emitting device; and
a color filter.

13. An image display system comprising:
an input section in which image information is received; and
a display section in which an image is output,
wherein the display section includes the display apparatus according to claim 11.

14. A lighting apparatus comprising:
the organic light-emitting device according to claim 6; and
an inverter circuit connected to the organic light-emitting device.

15. The lighting apparatus according to claim 14 further comprising a color filter.

16. An electrophotographic image-forming apparatus comprising:
a light source including a plurality of the organic light-emitting devices according to claim 6; and
a photosensitive member on which a latent image is formed by being exposed to light emitted by the light source.
